(19) United States
(12) Patent Application Publication
(10) Pub. No.: US 2024/0417854 A1
(43) Pub. Date: Dec. 19, 2024

(54) MODULATING THERMAL CONDUCTIVITY TO CONTROL COOLING OF SHOWERHEAD

(71) Applicant: LAM RESEARCH CORPORATION, Fremont, CA (US)

(72) Inventors: Troy GOMM, Tigard, OR (US); Kadthala R. NARENDRNATH, San Jose, CA (US); John B. ALEXY, Wilsonville, OR (US); Rahul RAJEEV, San Jose, CA (US)

(21) Appl. No.: 18/701,429

(22) PCT Filed: Oct. 26, 2022
(86) PCT No.: PCT/US2022/047793

§ 371 Date: Apr. 15, 2024

Related U.S. Application Data
(60) Provisional application No. 63/273,555, filed on Oct. 29, 2021.

(51) Int. Cl. C23C 16/455; C23C 16/505

(52) U.S. Cl. CPC C23C 16/45572; C23C 16/45565; C23C 16/505

(57) ABSTRACT

A cooling plate for a showerhead in a substrate processing system includes a first portion that defines a first path through the cooling plate. The first portion includes a first inlet configured to receive flow of a first fluid and a first outlet in fluid communication with the first inlet. The first path is in fluid communication with the first inlet and the first outlet. The cooling plate includes a second portion that defines a second path through the cooling plate. The second portion comprises a second inlet configured to receive flow of a second fluid and a second outlet in fluid communication with the second inlet, the second path is in fluid communication with the second inlet and the second outlet, and the second path is not in fluid communication with the first path, the first inlet, and the first outlet.

### CROSS-REFERENCE TO RELATED APPLICATIONS

This application claims the benefit of U.S. Provisional Application No. 63/273,555, filed on Oct. 29, 2021. The entire disclosure of the application referenced above is incorporated herein by reference.

### FIELD

The present disclosure relates to cooling showerheads in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of processing chambers (also called process modules) to perform deposition, etching, and other treatments of substrates such as semiconductor wafers. Examples of processes that may be performed on a substrate include, but are not limited to, plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.), and cleaning processes.

During processing, a substrate is arranged on a substrate support such as a pedestal, an electrostatic chuck (ESC), etc. in a processing chamber of the substrate processing system. During deposition, gas mixtures including one or more precursors are introduced into the processing chamber and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma. During deposition, etching, and cleaning, the gas mixtures and cleaning gas are supplied to the processing chamber using a gas distribution device such as a showerhead.

### SUMMARY

A cooling plate for a showerhead in a substrate processing system includes a first portion that defines a first path through the cooling plate. The first portion includes a first inlet configured to receive flow of a first fluid and a first outlet in fluid communication with the first inlet. The first path is in fluid communication with the first inlet and the first outlet. The cooling plate includes a second portion that defines a second path through the cooling plate. The second portion comprises a second inlet configured to receive flow of a second fluid and a second outlet in fluid communication with the second inlet, the second path is in fluid communication with the second inlet and the second outlet, and the second path is not in fluid communication with the first path, the first inlet, and the first outlet.

In other features, the second portion includes a first surface and a second surface and the second path is defined between the first surface and the second surface. The second path is serpentine. The cooling plate further includes a first set of fins that extend from the first surface toward the second surface and a second set of fins that extend from the second surface toward the first surface, wherein the first set of fins and the second set of fins define a serpentine path. The first set of fins does not contact the second surface and the second set of fins does not contact the first surface. The first set of are interleaved with the second set of fins. The first set of fins and the second set of fins do not connect the first surface to the second surface. The serpentine path is configured to alternately flow the second fluid in a first direction from the first surface toward the second surface and in a second direction from the second surface toward the first surface.

In other features, a cooling assembly includes the cooling plate and the showerhead. The second portion of the cooling plate is in direct contact with the showerhead.

A cooling assembly for a substrate processing system includes a cooling plate. The cooling plate includes a first portion defining a first path through the cooling plate, the first portion includes a first inlet configured to receive flow of a first fluid and a first outlet in fluid communication with the first inlet, the first path is in fluid communication with the first inlet and the first outlet, and the cooling plate includes a second portion. The cooling assembly includes a showerhead, the second portion is located between the first portion of the cooling plate and the showerhead, and the second portion is configured to provide heat transfer between the first portion of the cooling plate and the showerhead. A plenum is defined at least one of in the second portion, in a portion of the showerhead in contact with the second portion, and between the second portion and the showerhead. The plenum defines a second path through at least one of the cooling plate and the showerhead, the plenum is in fluid communication with a second inlet configured to receive flow of a second fluid and a second outlet, and wherein the plenum is not in fluid communication with the first path, the first inlet, and the first outlet.

In other features, the plenum is defined in the second portion. The plenum is defined in the showerhead. The plenum is defined between the second portion and the showerhead. The plenum is defined in a heat transfer plate located between the second portion and the showerhead.

A system for cooling a showerhead of a substrate processing system includes a cooling plate, a first inlet and a first outlet in fluid communication with a coolant assembly, a first path defined through the cooling plate, in fluid communication with the first inlet and the first outlet, and configured to receive flow of a liquid coolant from the coolant assembly, a second inlet and a second outlet in fluid communication with a heat transfer gas assembly, and a second path defined through the cooling plate and in fluid communication with the heat transfer gas assembly. The second path is configured to receive flow of a heat transfer gas from the heat transfer gas assembly. The second path is not in fluid communication with the first path.

In other features, the system further includes the showerhead. The cooling plate includes a first portion and a second portion. The second portion is located between the first portion and the second portion and in contact with the showerhead. The first path is defined in the first portion and the second path is defined in the second portion. The second path defines a serpentine path through the second portion.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example of a substrate processing system according to the present disclosure;

FIG. 2A is an example cooling assembly for a showerhead according to the present disclosure;

FIG. 2B is a plan view of an example cooling plate of the cooling assembly of FIG. 2A;

FIG. 2C is a plan view of another example cooling plate of the cooling assembly of FIG. 2A;

FIGS. 3A-3E are example cooling assemblies according to the present disclosure;

FIG. 3F is a plan view of a stem of a showerhead of the cooling assembly of FIG. 3E;

FIG. 4 is a system including an example cooling assembly according to the present disclosure; and

FIG. 5 illustrates steps of an example method of controlling thermal conductivity of a cooling assembly for a showerhead according to the present disclosure.

In the drawings, reference numbers may be reused to identify similar and/or identical elements.

### DETAILED DESCRIPTION

Gas distribution devices such as showerheads may comprise heating and/or cooling devices to control a temperature of the showerhead during processing. For example, during some process such as PECVD, RF power is supplied to an electrode within a showerhead to generate plasma. RF power, plasma generated by the RF power, and heat from a substrate support (e.g., a pedestal, electrostatic chuck, etc.) heat the showerhead. Accordingly, a cooling device (e.g., one or more cooling plates) may be coupled to the showerhead to cool the showerhead. In some examples, a cooling fluid (e.g., water) is flowed through the cooling plate to cool the showerhead.

Conversely, other types of process may not heat the showerhead. For example, cleaning processes may be associated with a significantly lower heat load than deposition or etching processes. However, a cooling device (e.g., a cooling plate containing water or another cooling fluid) may still be coupled to the showerhead during cleaning processes. Accordingly, during cleaning processes, a heater may be used to heat the showerhead to compensate for the cooling provided by the cooling devices. Heating the showerhead to offset a cooling load provided by the cooling plate consumes power and increases operation and manufacturing complexity.

Showerhead cooling systems and methods according to the present disclosure implement a cooling plate assembly with multiple (e.g., two or more) independent fluid paths or cavities configured to flow different heat transfer fluids through a cooling plate. For example, a first path is defined within the cooling assembly to flow a first fluid (e.g., water) through the cooling plate to cool the showerhead during a first process or set of processes (e.g., deposition and/or etching). A second path, independent of (i.e., not in fluid communication with) the first path, is defined within the cooling assembly to provide a second fluid (e.g., a heat transfer gas having a high thermal conductivity, such as helium) to the cooling plate during the first process or set of processes but not a second process (e.g., a cleaning process). Instead, during the second process, the second fluid is purged from the second path and/or a third fluid having a thermal conductivity lower than the second fluid is supplied to the second path.

Accordingly, during processes requiring showerhead cooling, greater thermal conductivity between the cooling plate and the showerhead is achieved. Conversely, during processes that do not require showerhead cooling, a lower thermal conductivity between the cooling plate and the showerhead is achieved.

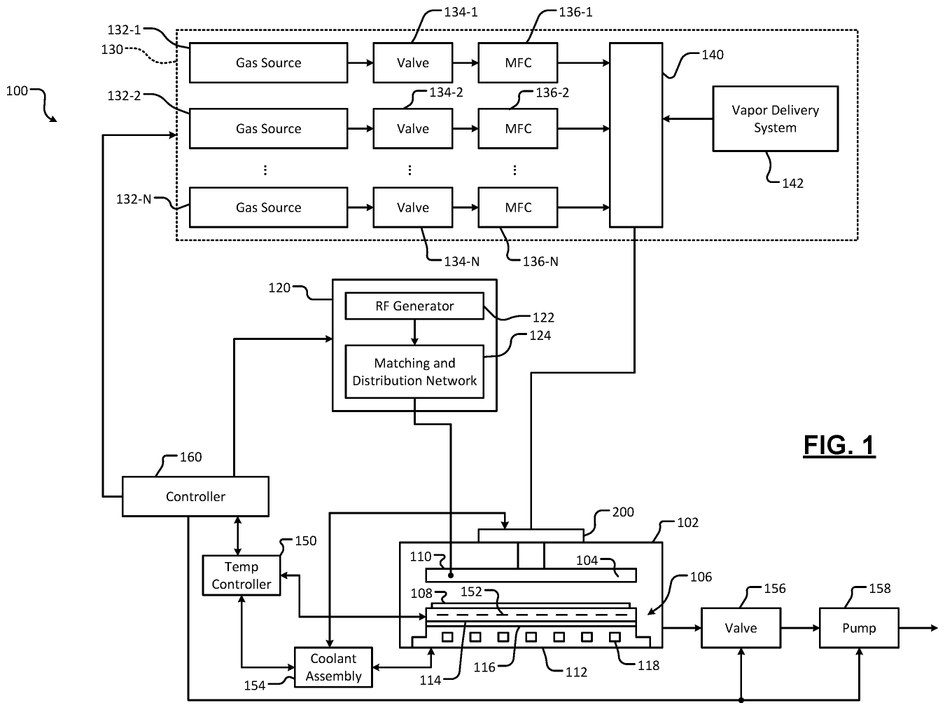

An example of a substrate processing system 100 is described with reference to FIG. 1, in which a processing chamber comprises a showerhead. The cooling assembly according to the present disclosure can be used in this and any other substrate processing system in which a processing chamber comprises a showerhead. The teachings of the present disclosure are not limited to cooling showerheads. Rather, any structure or device can be cooled using the cooling assembly. Further, the teachings of the present disclosure are not limited to providing cooling only. Rather, the teachings can be used to provide heating instead of cooling by flowing a heating fluid instead of a cooling fluid through the cooling assembly.

Referring now to FIG. 1, an example of a substrate processing system 100 comprising a processing chamber 102 is configured to generate capacitively coupled plasma. The processing chamber 102 encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may comprise a gas distribution device such as a showerhead 110 that introduces and distributes process gases. The showerhead 110 may comprise a stem portion having one end connected to a top surface of the processing chamber 102. A base portion of the showerhead 110 is generally cylindrical and extends radially outwardly from an opposite end of the stem portion at a location that is spaced from the top surface of the processing chamber 102. A substrate-facing surface or faceplate of the base portion of the showerhead 110 comprises a plurality of holes through which vaporized precursor, process gas, cleaning gas, or purge gas flows.

The ESC 106 comprises a baseplate 112 that acts as a lower electrode. The baseplate 112 supports a heating plate 114, which may correspond to a ceramic multi-zone heating plate. A thermal resistance layer 116 may be arranged between the heating plate 114 and the baseplate 112. The baseplate 112 may comprise one or more channels 118 for flowing coolant through the baseplate 112.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may comprise an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 comprises one or more gas sources 132-1, 132-2, . . . , and 132-N(collectively gas sources 132), where N is an integer greater than zero. The gas sources 132 are connected by valves 134-1, 134-2, . . . , and 134-N(collectively valves 134) and mass flow controllers 136-1, 136-2, . . . , and 136-N(collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, and/or purge gases.

A temperature controller 150 may be connected to a plurality of thermal control elements (TCEs) 152 arranged in the heating plate 114. The temperature controller 150 may be used to control the plurality of TCEs 152 to control a temperature of the ESC 106 and the substrate 108. The temperature controller 150 may communicate with a coolant assembly 154 to control coolant flow through the channels 118. For example, the coolant assembly 154 may comprise a coolant pump, a reservoir, and one or more temperature sensors (not shown). The temperature controller 150 operates the coolant assembly 154 to selectively flow the coolant through the channels 118 to cool the ESC 106. A valve 156 and pump 158 may be used to evacuate reactants from the processing chamber 102. A system controller 160 controls the components of the substrate processing system 100.

A cooling assembly 200 according to the present disclosure, which is described below in more detail, is attached to the showerhead 110. The coolant assembly 154 (or a separate coolant assembly) supplies a first fluid (e.g., a coolant such as water) to a first path defined within the cooling assembly 200. The first fluid may be a same coolant supplied to the channels 118 of the baseplate 112 or a different coolant. For example, the coolant assembly 154 may represent multiple pumps, reservoirs, manifolds, etc. configured to provide same or different fluids to respective locations. Similarly, the coolant assembly 154 (or a separate assembly) supplies one or more second fluids (e.g., a heat transfer gas) to a second path defined within the cooling assembly 200.

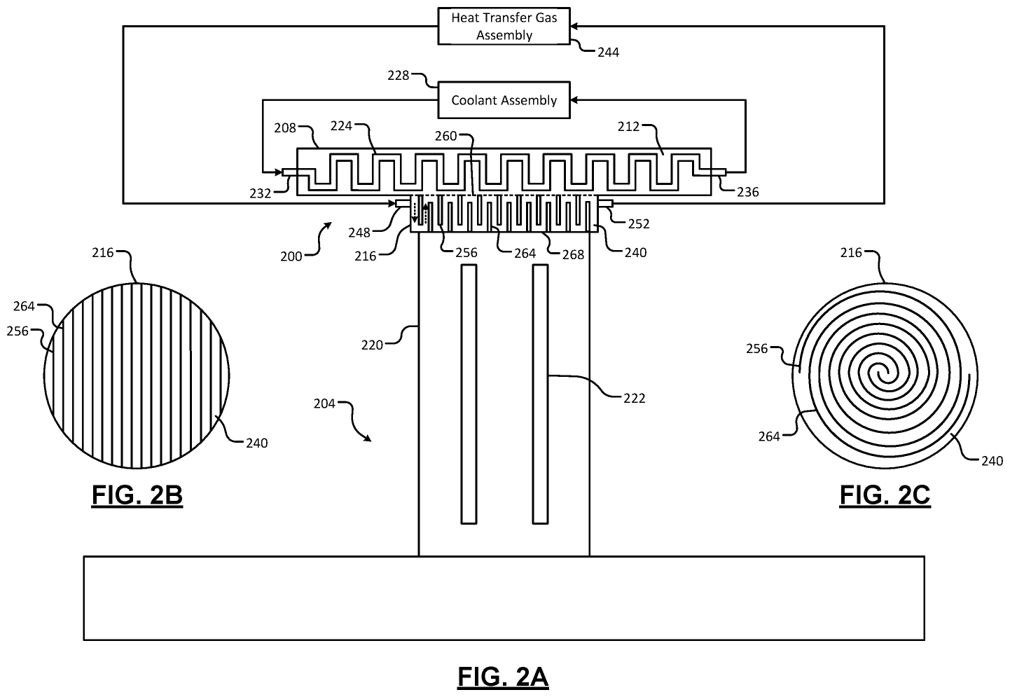

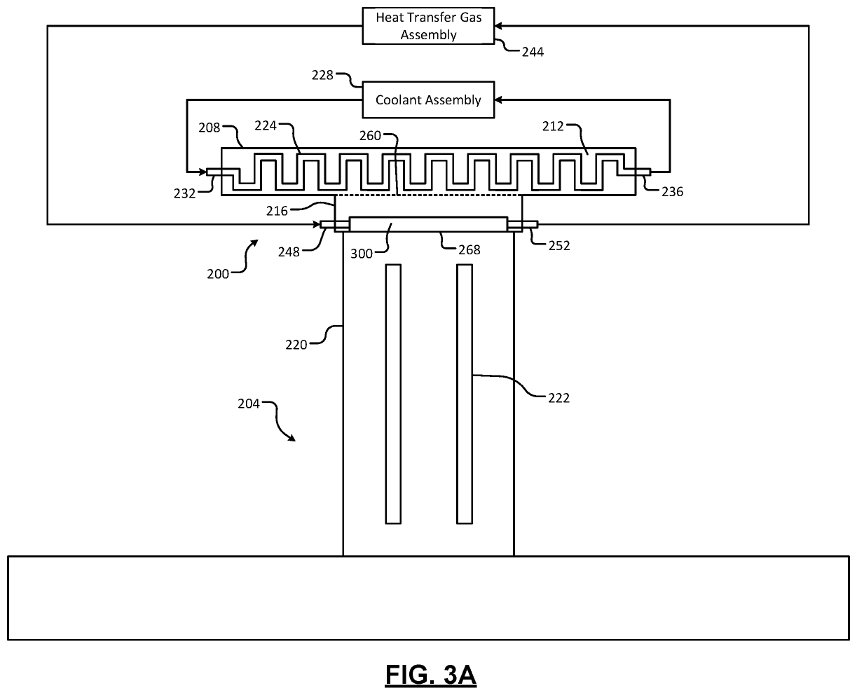

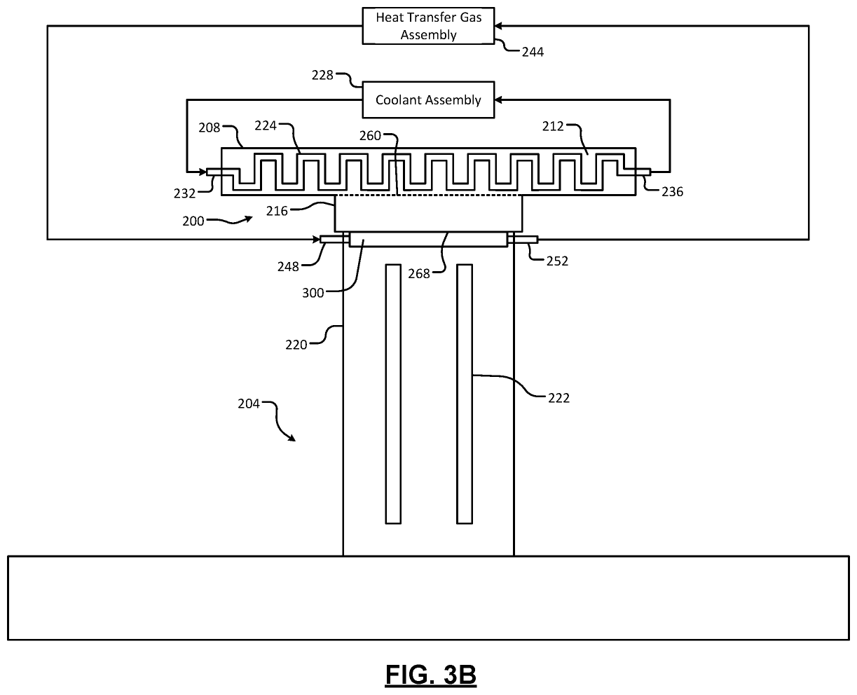

Referring now to FIG. 2A, an example of the cooling assembly 200 for a showerhead 204 according to the present disclosure is shown in more detail. The cooling assembly 200 comprises a single cooling plate 208 having a first (e.g., upper) portion 212 and a second (e.g., lower) portion 216 disposed above and in thermal contact with a stem 220 of the showerhead 204. For example, the cooling plate 208 is comprised of a material having a high thermal conductivity, such as aluminum, copper, etc. The first portion 212 and the second portion 216 may be comprised of same or different materials. The first portion 212 may have a greater diameter than the second portion 216.

Although shown as comprising the single cooling plate 208, in other examples the cooling assembly 200 may comprise multiple cooling plates. In some examples, the showerhead 204 (e.g., the stem 220) may comprise one or more heaters 222 configured to heat the showerhead 204. The first portion 212 and the second portion 216 may be integral or separately formed (i.e., machined from a single block or separately formed and brazed together). In some examples, the first portion 212 and the second portion 216 are separably attached such that the first portion 212 or the second portion 216 may be separately removed for replacement, servicing, cleaning, etc.

The cooling assembly 200 is configured to provide multiple levels or stages of thermal conductivity (i.e., adjustable thermal conductivity) between the cooling plate 208 and the showerhead 204. For example, the first portion 212 defines a first channel or path 224 (or a first set of channels or paths) for coolant (e.g., water) to flow through the cooling plate 208. In one example, a coolant assembly 228 supplies the coolant to a first inlet 232 of the first portion 212. Cold coolant flows into the first inlet 232, draws heat from the first portion 212, and exits the first portion 212 as hot coolant from a first outlet 236. The hot coolant returns to the coolant assembly 228 to be re-cooled. In this manner, the first path 224 is configured to flow coolant through the first portion 212 to cool the showerhead 204.

The coolant may be flowed through the first portion 212 during processes requiring cooling (e.g., deposition and etching) as well as processes that do not require cooling (e.g., cleaning). For example, it may not be feasible to selectively discontinue flow of the coolant through the first portion 212, or the coolant assembly 228 and associated control may not be configured to discontinue flow of the coolant through the first portion 212. In other words, the coolant may continue to draw heat from the first portion 212 and apply a cooling load to the showerhead 204 when cooling is not necessary or desirable.

The second portion 216 defines a second channel or path 240 (or a second set of channels or paths) for a heat transfer fluid to flow through the cooling plate 208. The second path 240 independent of the first path 224. In other words, the second path 240 is not in fluid communication with the first path 224. Accordingly, the coolant supplied to the first path 224 from the coolant assembly 228 is not supplied to the second path 240. Conversely, the heat transfer fluid supplied to the second path 240 is not supplied to the first path 224.

The heat transfer fluid may comprise a heat transfer gas (e.g., helium, argon, etc.) or a heat transfer liquid (e.g., a fluorinated heat transfer liquid, liquid potassium, etc.). As an example, a heat transfer gas assembly 244 selectively supplies a heat transfer gas to a second inlet 248 of the second portion 216. The heat transfer gas flows into the second inlet 248 and exits the second portion 216 from a second outlet 252 to return to the heat transfer gas assembly 244.

The heat transfer gas may only be selectively supplied to the second portion 216. In other words, the heat transfer gas may be supplied during some processes that require cooling of the showerhead 204 (e.g., deposition, etching, etc.) and is not supplied during processes where cooling is not desired (e.g., cleaning). The heat transfer gas may be continuously flowed through the second path 240 during selected processes or supplied to the second path 240 to charge the second portion 216 with the heat transfer gas. In some examples, a pressure of the heat transfer gas supplied to the second path 240 may be varied to provide a desired heat transfer value.

In processes where cooling of the showerhead 204 is not desired, the heat transfer gas in the second path 240 is pumped out and/or replaced. For example, the heat transfer gas assembly 244 is configured to purge the second path 240 to remove the heat transfer gas. In some examples, the heat transfer gas assembly 244 pumps the second path 240 down to vacuum. In other examples, the heat transfer gas assembly 244 replaces the heat transfer gas with another gas (e.g., air) that has a lower thermal conductivity than the heat transfer gas. In this manner, the thermal conductivity of the second portion 216 can be controlled (i.e., varied). In other words, the second portion 216 has a first thermal conductivity when cooling of the showerhead 204 is desired and the second portion 216 is charged with and/or flowing the heat transfer gas. Conversely, the second portion 216 has a second thermal conductivity that is lower than the first thermal conductivity when the heat transfer gas is not supplied to the second portion 216.

As shown in FIG. 2A and in a plan (top-down) view in FIGS. 2B and 2C, the second path 240 is configured to maximize a surface area while minimizing a volume within second portion 216. For example, the second path 240 defines a serpentine or tortuous path through the second portion 216. In one example, a first set of fins 256 (or a continuous fin or rim) extends downward from a first (e.g., upper) surface 260 of the second portion 216. A second set of fins 264 (or a continuous fin or rim) extends upward from a second (e.g., lower) surface 268 of the second portion 216. The first fins 256 and the second fins 264 are interleaved or interdigitized to form the second path 240. The first fins 256 and the second fins 264 may be machined into the second portion 216, formed using additive manufacturing, brazed into the second portion 216, etc.

As shown in FIG. 2B, the first fins 256 and the second fins 264 extend in a generally straight configuration across the second portion 216 but other suitable shapes and configurations may be used. In this configuration, the first fins 256 and the second fins 264 direct the heat transfer gas upward and downward along the second path 240 as indicated by arrows in FIG. 2A. For example, as shown in FIG. 2C, the first fin 256 and the second fin 264 have complementary spiral shapes. In these examples, the first surface 260 (e.g., a cold side) and the second surface 268 (e.g., a hot side) are not in direct physical contact with one another. In other words, the first fins 256 are not in direct physical thermal contact with the second surface 268. Similarly, the second fins 264 are not in direct physical thermal contact with the first surface 260. Accordingly, when the heat transfer gas is not present within the second portion 216, thermal conductivity between the first surface 260 and the second surface 268 is minimized.

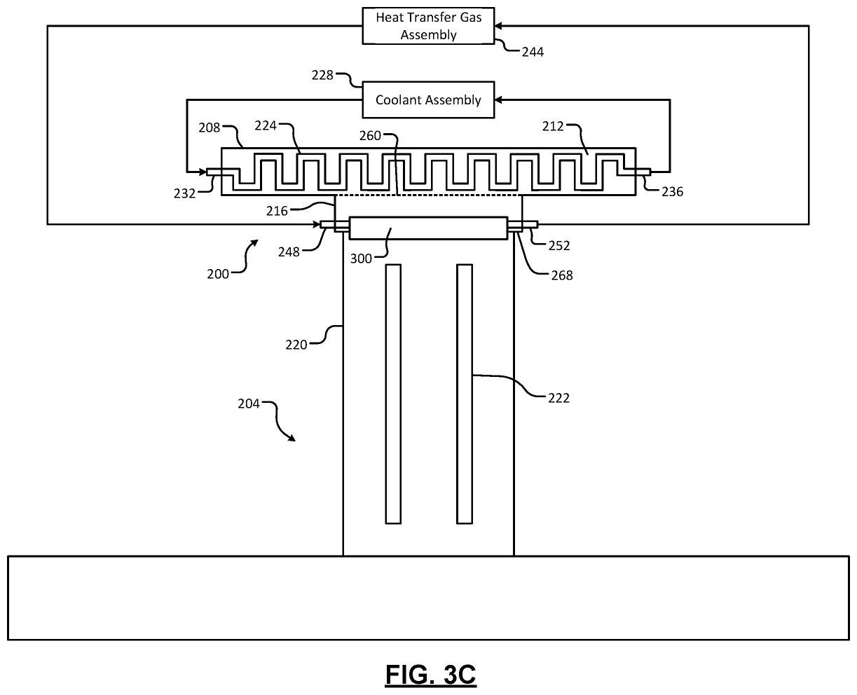

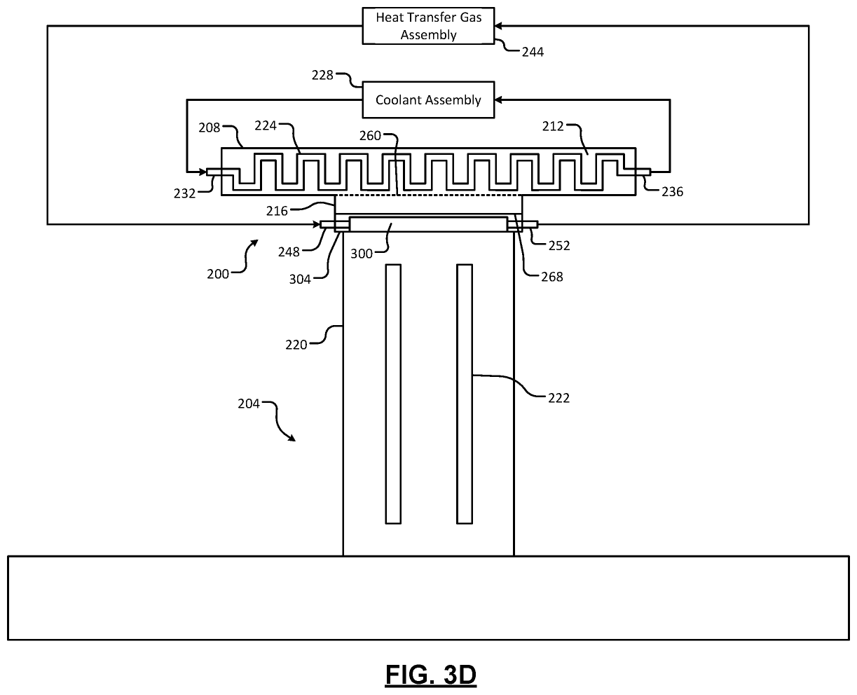

FIG. 3A shows another example of the cooling assembly 200. In this example, a void or plenum 300 is defined within the second portion 216. For example, as shown, the plenum 300 is machined into the second surface 268 of the second portion 216. The plenum 300 may be defined between the second surface 268 of the second portion 216 and the stem 220. Although shown as a single plenum, the second portion 216 may comprise two or more of the plenums 300. For example, the second portion 216 may comprise two of the plenums 300 in a vertical configuration (i.e., one plenum located above the other). In another example, the second portion 216 may comprise two or more of the plenums 300 in a radial configuration. For example, the plenums may be be defined as two or more concentric rings in the second surface 228.

The heat transfer gas assembly 244 selectively supplies the heat transfer gas or liquid to the plenum 300 in a similar manner as is described in FIG. 2A. In this manner, thermal conductivity between the cooling plate 208 and the showerhead 204 can be controlled and varied for respective processes.

In another example shown in FIG. 3B, the void or plenum 300 is defined in the showerhead 204. For example, as shown, the plenum 300 is defined in an upper portion of the stem 220. The heat transfer gas assembly 244 selectively supplies the heat transfer gas or liquid to the plenum 300 in a similar manner as is described in FIGS. 2A and 3A. In this manner, thermal conductivity between the cooling plate 208 and the showerhead 204 can be controlled and varied for respective processes.

In another example shown in FIG. 3C, the void or plenum 300 is defined in and between the cooling plate 208 and the showerhead 204. For example, as shown, the plenum 300 defined in both the second surface 268 of the second portion 216 and in the upper portion of the stem 220. The heat transfer gas assembly 244 selectively supplies the heat transfer gas or liquid to the plenum 300 in a similar manner as is described in FIGS. 2A, 3A, and 3B.

In another example shown in FIG. 3D, the plenum 300 is defined in a separate heat transfer plate 304 disposed between the cooling plate 208 and the showerhead 204. For example, the heat transfer plate 304 comprises a thermally conductive material such as copper, aluminum, etc. and is in direct physical contact with the second portion 216 of the cooling plate 208 and the stem 220 of the showerhead 204. The heat transfer gas assembly 244 selectively supplies the heat transfer gas or liquid to the plenum 300 in a similar manner as is described in FIGS. 2A, 3A, 3B, and 3C.

In another example shown in FIG. 3E and in a plan (top-down) view in FIG. 3F, one or more of the plenums 300 are defined in a sidewall 308 of the stem 220. The plenums 300 may be in fluid communication with one another such that when heat transfer gas is supplied to the second inlet 248, each of the plenums 300 is filled with the heat transfer gas to increase a thermal conductivity of the showerhead 204. Accordingly, the heat transfer gas assembly 244 selectively supplies the heat transfer gas or liquid to the plenums 300 in a similar manner as is described in FIGS. 2A, 3A, 3B, 3C, and 3D.

Although as described in FIGS. 3B-3F the plenum 300 is shown disposed in different locations, in any of these examples the plenum 300 may be configured with the second path 240 described in FIG. 2A. In other words, instead of defining a void, any of the plenums 300 may be configured to define a torturous or serpentine path through the second portion 216, the stem 220 of the showerhead 204, the heat transfer plate 304, and combinations thereof.

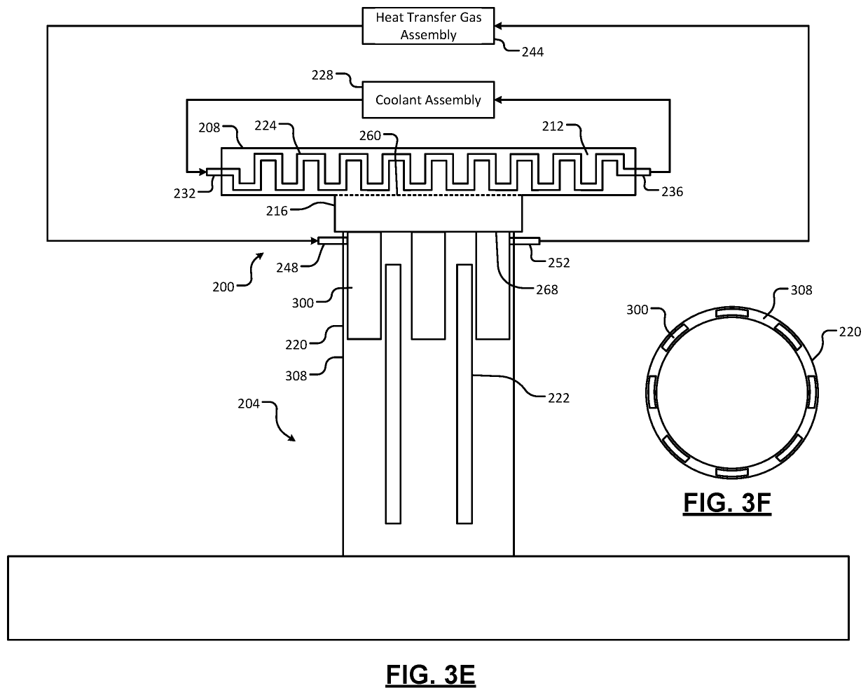

Referring now to FIG. 4, a system 400 comprises a temperature controller 404 (e.g., corresponding to the temperature controller 150 of FIG. 1) configured to selectively supply heat transfer fluid (e.g., gas) to a cooling assembly 408 according to the present disclosure. For example, the cooling assembly 408 comprises a cooling plate 410 with a first portion 412 and a second portion 416 (e.g., corresponding to the first portion 212 and the second portion 216 described above). The temperature controller 404 controls a coolant assembly 420 and a heat transfer gas assembly 424 to supply coolant to the first portion 412 and selectively supply heat transfer gas to the second portion 416 to cool a showerhead 428 as described below in more detail.

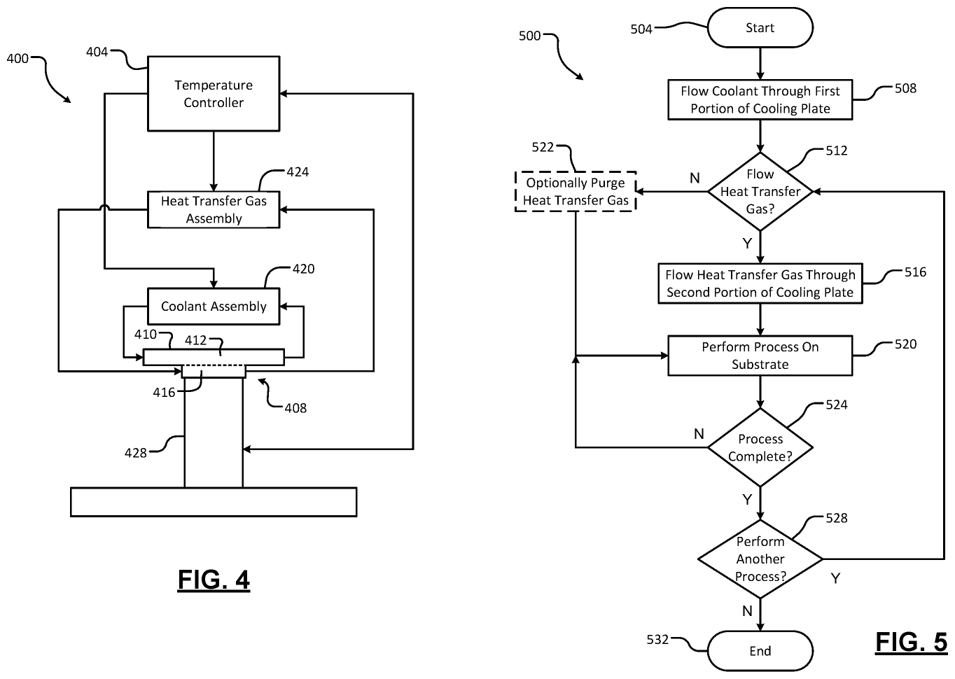

Referring now to FIG. 5 and with continued reference to FIG. 4, a method 500 of controlling the thermal conductivity of the cooling assembly 408 according to the present disclosure is shown. One or more steps may be performed prior to the method starting at 504. For example, a substrate may be arranged on a substrate support, various processes may be performed on the substrate prior to and/or subsequent to arranging the substrate on the substrate support (in a same or different processing chamber), etc.

At 508, the method 500 (e.g., the temperature controller 404) controls the coolant assembly 420 to flow coolant (e.g., liquid coolant, such as water) through the first portion 412 of the cooling plate 410. At 512, the method 500 (e.g., the temperature controller 404) determines whether to charge and/or flow heat transfer gas to the second portion 416 of the cooling plate 410. For example, the temperature controller 404 may determine which process is being performed on the substrate and determine whether to flow heat transfer gas to the second portion 416 based on the determined process. If true, the method 500 continues to 516. If false, the method 500 continues to 520. In examples where cooling of the showerhead 428 is not required, the method 500 may optionally purge the heat transfer gas from the second portion 416 at 522.

At 516, the method 500 (e.g., the temperature controller 404) controls flow of the heat transfer gas to the second portion 416. For example, the temperature controller 404 controls the heat transfer gas assembly 424 to control the flow of the heat transfer gas based on a desired thermal conductivity of the cooling plate 410. The thermal conductivity of the cooling plate 410 may be modulated by controlling a flow rate, pressure, type, etc. of the heat transfer gas supplied to the second portion 416. In other words, different processes may have different cooling requirements and, therefore, a different desired thermal conductivity.

At 520, a process (e.g., deposition, etching, cleaning, etc.) is performed on the substrate. In some examples, the thermal conductivity of the cooling plate 410 may be modulated (i.e., tuned) during the process. For example, the temperature controller 404 is configured to adjust the pressure and/or flow of the heat transfer gas supplied to the second portion 416 to increase and/or decrease the thermal conductivity of the cooling plate 410. For example, the temperature controller 404 may be responsive to estimated or sensed (e.g., using one or more temperature sensors) temperatures of the showerhead 428. In other examples, the temperature controller 404 may be configured to control one or more heaters to heat the showerhead 428.

At 524, the method 500 determines whether the process is complete. If true, the method 500 continues to 528. If false, the method 500 continues to 520. At 528, the method 500 determines whether to perform another process on the substrate. If true, the method 500 continues to 512. If false, the method 500 ends at 532.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A cooling plate for a showerhead in a substrate processing system, the cooling plate comprising:
a first portion that defines a first path through the cooling plate, wherein the first portion comprises a first inlet configured to receive flow of a first fluid and a first outlet in fluid communication with the first inlet, and wherein the first path is in fluid communication with the first inlet and the first outlet; and
a second portion that defines a second path through the cooling plate, wherein the second portion comprises a second inlet configured to receive flow of a second fluid and a second outlet in fluid communication with the second inlet, wherein the second path is in fluid communication with the second inlet and the second outlet, and wherein the second path is not in fluid communication with the first path, the first inlet, and the first outlet.

2. The cooling plate of claim 1, wherein the second portion includes a first surface and a second surface and the second path is defined between the first surface and the second surface.

3. The cooling plate of claim 2, wherein the second path is serpentine.

4. The cooling plate of claim 3, further comprising a first set of fins that extend from the first surface toward the second surface and a second set of fins that extend from the second surface toward the first surface, wherein the first set of fins and the second set of fins define a serpentine path.

5. The cooling plate of claim 4, wherein the first set of fins does not contact the second surface and the second set of fins does not contact the first surface.

6. The cooling plate of claim 4, wherein the first set of are interleaved with the second set of fins.

7. The cooling plate of claim 4, wherein the first set of fins and the second set of fins do not connect the first surface to the second surface.

8. The cooling plate of claim 4, wherein the serpentine path is configured to alternately flow the second fluid in a first direction from the first surface toward the second surface and in a second direction from the second surface toward the first surface.

9. A cooling assembly comprising the cooling plate of claim 1 and the showerhead.

10. The cooling assembly of claim 9, wherein the second portion of the cooling plate is in direct contact with the showerhead.

11. A cooling assembly for a substrate processing system, the cooling assembly comprising:
a cooling plate that comprises
a first portion defining a first path through the cooling plate, wherein the first portion comprises a first inlet configured to receive flow of a first fluid and a first outlet in fluid communication with the first inlet, and wherein the first path is in fluid communication with the first inlet and the first outlet, and
a second portion;
a showerhead, wherein the second portion is located between the first portion of the cooling plate and the showerhead, and wherein the second portion is configured to provide heat transfer between the first portion of the cooling plate and the showerhead; and
a plenum defined at least one of (i) in the second portion, (ii) in a portion of the showerhead in contact with the second portion, and (iii) between the second portion and the showerhead, wherein the plenum defines a second path through at least one of the cooling plate and the showerhead, wherein the plenum is in fluid communication with a second inlet configured to receive flow of a second fluid and a second outlet, and wherein the plenum is not in fluid communication with the first path, the first inlet, and the first outlet.

12. The cooling assembly of claim 11, wherein the plenum is defined in the second portion.

13. The cooling assembly of claim 11, wherein the plenum is defined in the showerhead.

14. The cooling assembly of claim 11, wherein the plenum is defined between the second portion and the showerhead.

15. The cooling assembly of claim 14, wherein the plenum is defined in a heat transfer plate located between the second portion and the showerhead.

16. A system for cooling a showerhead of a substrate processing system, the system comprising:
a cooling plate;
a first inlet and a first outlet in fluid communication with a coolant assembly;
a first path defined through the cooling plate and in fluid communication with the first inlet and the first outlet, wherein the first path is configured to receive flow of a liquid coolant from the coolant assembly;
a second inlet and a second outlet in fluid communication with a heat transfer gas assembly; and
a second path defined through the cooling plate and in fluid communication with the heat transfer gas assembly, wherein the second path is configured to receive flow of a heat transfer gas from the heat transfer gas assembly, and wherein the second path is not in fluid communication with the first path.

17. The system of claim 16, further comprising the showerhead.

18. The system of claim 17, wherein the cooling plate comprising a first portion and a second portion, and wherein the second portion is located between the first portion and the second portion and in contact with the showerhead.

19. The system of claim 18, wherein the first path is defined in the first portion and the second path is defined in the second portion.

20. The system of claim 19, wherein the second path defines a serpentine path through the second portion.
